(19) United States
(12) Patent Application Publication
(10) Pub. No.: US 2026/0312482 A1
(43) Pub. Date: Oct. 8, 2026

(54) DRIVING VOLTAGE ADJUSTING CIRCUIT AND POWER SUPPLYING SYSTEM

(71) Applicant: Universal Global Technology (Huizhou) Co., Ltd., Guangdong Province (CN)

(72) Inventor: CHIU YI PAI, Guangdong Province (CN)

(21) Appl. No.: 19/575,953

(22) Filed: Mar. 24, 2026

(30) Foreign Application Priority Data
Apr. 8, 2025 (CN) 202510438697.9

(51) Int. Cl. H02M 1/088; H02M 1/00; H02M 3/158; H03K 7/08; H03K 17/14

(52) U.S. Cl. CPC H02M 1/088; H02M 1/0054; H02M 3/158; H03K 7/08; H03K 17/145; H03K 2217/0036

(57) ABSTRACT

A driving voltage adjusting circuit and a power supplying system are proposed. The driving voltage adjusting circuit includes a detecting unit, a voltage dividing unit and an adjusting unit. The detecting unit is configured to detect a temperature of the switching element of the voltage converter. The voltage dividing unit is electrically connected to the detecting unit and the voltage converter, and receives a driving voltage. The voltage dividing unit divides the driving voltage according to the temperature of the switching element to generate a dividing voltage. The adjusting unit is electrically connected to the voltage dividing unit, and receives an input voltage and the dividing voltage. The adjusting unit adjusts the input voltage according to the dividing voltage to output the driving voltage, and the driving voltage is transmitted to the voltage converter. The temperature is positively correlated with the driving voltage.

### RELATED APPLICATIONS

This application claims priority to China Application Serial Number 202510438697.9, filed Apr. 8, 2025, which is herein incorporated by reference.

### BACKGROUND

### Technical Field

The present disclosure relates to a driving voltage adjusting circuit and a power supplying system, and particularly to a driving voltage adjusting circuit and a power supplying system for a voltage converter.

### Description of Related Art

In existing DC-DC voltage converters, the predominant power loss under light-load conditions stems from switching of switching elements of the converters, while under heavy-load conditions, the predominant power loss is attributed to conduction loss of the switching elements. Since the internal resistance of the switching element varies with the driving voltage, the power loss of the voltage converter can be effectively reduced by appropriately adjusting the driving voltage of the switching element of the voltage converter.

Additionally, since the impedance of the switching element of the voltage converter changes with temperature, the power loss of the voltage converter is also positively correlated with temperature. In view of this, developing a driving voltage adjusting circuit that can adjust a driving voltage according to a temperature of a switching element and a power supplying system has become a worthwhile research and development objective for relevant industry players.

### SUMMARY

According to one aspect of the present disclosure, a driving voltage adjusting circuit includes a detecting unit, a voltage dividing unit, and an adjusting unit. The detecting unit is disposed adjacent to a switching element of a voltage converter, and is configured to detect a temperature of the switching element of the voltage converter. The voltage dividing unit is electrically connected to the detecting unit and the voltage converter, and receives a driving voltage. The voltage dividing unit divides the driving voltage according to the temperature of the switching element to generate a dividing voltage. The adjusting unit is electrically connected to the voltage dividing unit, and receives an input voltage and the dividing voltage. The adjusting unit adjusts the input voltage according to the dividing voltage to output the driving voltage, and the driving voltage is transmitted to the voltage converter. The temperature is positively correlated with the driving voltage.

According to another aspect of the present disclosure, a power supplying system includes a voltage converter and a driving voltage adjusting circuit. The voltage converter is driven by a driving voltage and includes a switching element set. The switching element set includes two switching elements. The driving voltage adjusting circuit includes a detecting unit, a voltage dividing unit, and an adjusting unit. The detecting unit is disposed adjacent to one of the two switching elements and configured to detect a temperature of the one of the two switching elements. The voltage dividing unit is electrically connected to the detecting unit and the voltage converter, and receives a driving voltage. The voltage dividing unit divides the driving voltage according to the temperature of the one of the two switching elements to generate a dividing voltage. The adjusting unit is electrically connected to the voltage dividing unit, and receives an input voltage and the dividing voltage. The adjusting unit adjusts the input voltage according to the dividing voltage to output the driving voltage, and the driving voltage is transmitted to the voltage converter. The temperature is positively correlated with the driving voltage.

### BRIEF DESCRIPTION OF THE DRAWINGS

The present disclosure can be more fully understood by reading the following detailed description of the embodiment, with reference made to the accompanying drawings as follows:

FIG. 1 is a block schematic diagram illustrating a driving voltage adjusting circuit according to a first embodiment of the present disclosure.

FIG. 2 is a circuit schematic diagram illustrating a voltage converter connected to the driving voltage adjusting circuit in FIG. 1.

FIG. 3 is a voltage schematic diagram illustrating the voltage converter connected to the driving voltage adjusting circuit in FIG. 2.

FIG. 4 is a schematic diagram illustrating a driving voltage adjusting circuit according to a second embodiment of the present disclosure.

FIG. 5 is a schematic diagram illustrating a driving voltage adjusting circuit according to a third embodiment of the present disclosure.

FIG. 6 is a schematic diagram illustrating a power supplying system according to a fourth embodiment of the present disclosure.

FIG. 7 is a circuit schematic diagram illustrating the power supplying system according to FIG. 6.

### DETAILED DESCRIPTION

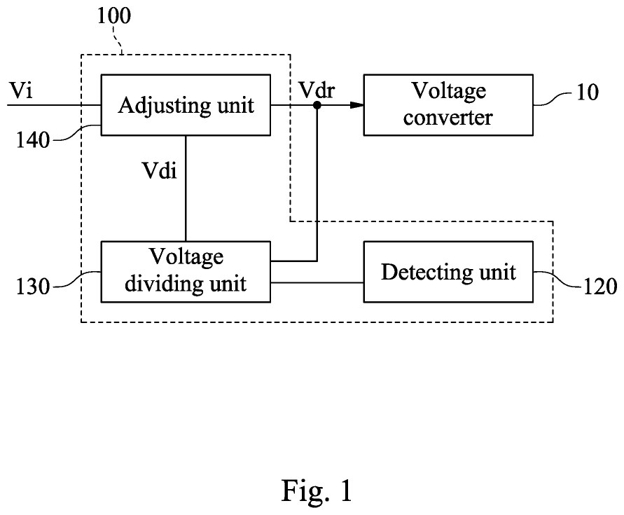

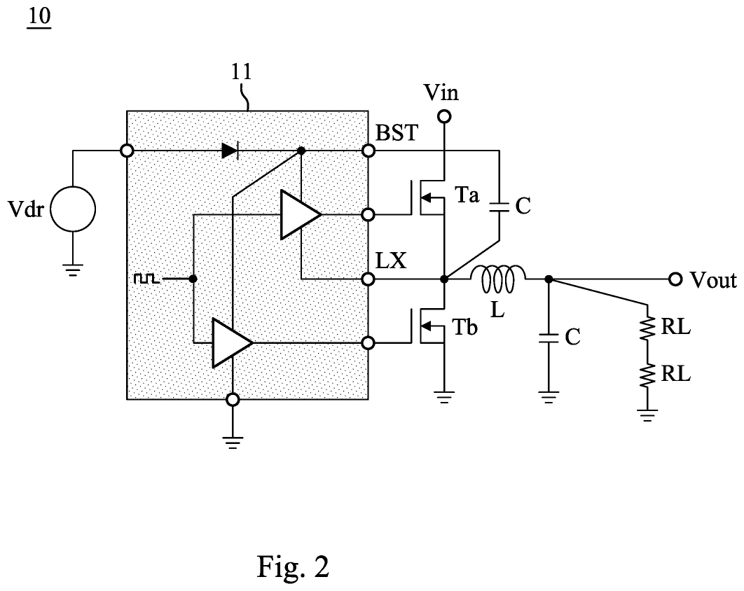

Reference is made to FIG. 1 and FIG. 2, FIG. 1 is a block schematic diagram illustrating a driving voltage adjusting circuit 100 according to a first embodiment of the present disclosure. FIG. 2 is a circuit schematic diagram illustrating a voltage converter 10 connected to the driving voltage adjusting circuit 100 in FIG. 1. The driving voltage adjusting circuit 100 includes a detecting unit 120, a voltage dividing unit 130, and an adjusting unit 140. The detecting unit 120 is disposed adjacent to a switching element (i.e., one of switching elements Ta and Tb in FIG. 2) of the voltage converter 10, and is configured to detect a temperature of the one of the switching elements Ta and Tb of the voltage converter 10. The voltage dividing unit 130 is electrically connected to the detecting unit 120 and the voltage converter 10, and receives a driving voltage Vdr. The voltage dividing unit 130 divides the driving voltage Vdr according to the temperature of the switching elements Ta and Tb to generate a dividing voltage Vdi. The adjusting unit 140 is electrically connected to the voltage dividing unit 130, and receives an input voltage Vi and the dividing voltage Vdi. The adjusting unit 140 adjusts the input voltage Vi according to the dividing voltage Vdi to output the driving voltage Vdr, and the driving voltage Vdr is transmitted to the voltage converter 10. The temperature is positively correlated with the driving voltage Vdr.

Specifically, the detecting unit 120 may be a thermistor with a negative temperature coefficient, the voltage dividing unit 130 may be a voltage dividing circuit composed of resistors connected in series, and the adjusting unit 140 may be a DC-DC converter or a low dropout regulator (LDO), but the present disclosure is not limited thereto.

In FIG. 2, the voltage converter 10 may be a DC-DC converter, which includes a pulse generation circuit 11, two switching elements Ta and Tb, a capacitor C, an inductor L and a load RL. The pulse generation circuit 11 is configured to input a pulse to the switching elements Ta and Tb. The switching elements Ta and Tb are driven by the driving voltage Vdr, and alternately turned on according to a voltage level of the pulse. The switching elements Ta and Tb may be metal-oxide-semiconductor field-effect transistors (MOSFETs). Internal resistance values of the switching elements decrease as the gate driving voltage Vdr increases. A voltage Vout is an output voltage of the voltage converter 10.

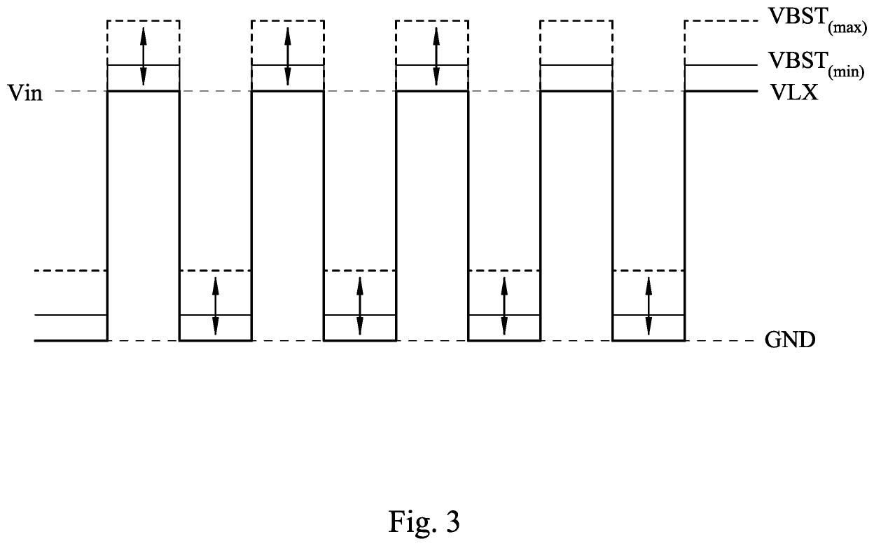

Reference is made to FIG. 2 and FIG. 3. FIG. 3 is a voltage schematic diagram illustrating the voltage converter 10 connected to the driving voltage adjusting circuit 100 in FIG. 2, in which a ground voltage GND, a voltage VLX at a terminal LX, a voltage range at a terminal BST, and a voltage Vin in the voltage converter 10 in FIG. 2 are only illustrated. The terminal BST is connected to a drain of the switching element Ta, and the terminal LX is connected to a source of the switching element Ta and the drain of the switching element Tb. The voltage VLX at the terminal LX is the same as the voltage Vin, while a voltage at the terminal BST is the voltage Vin plus the driving voltage Vdr. As the driving voltage Vdr changes with the temperature, the voltage at the terminal BST is between a maximum value VBST₍ₘₐₓ₎ and a minimum value VBST₍ₘᵢₙ₎, and a voltage difference between the voltage at the terminal BST and the voltage VLX is also variable.

Furthermore, during an operation of the voltage converter 10, the switching elements Ta and Tb are alternately turned on and generate heat loss. When the temperature of the switching elements Ta and Tb of the voltage converter 10 rises, the detecting unit 120 detects a temperature of one of the switching elements Ta and Tb, divides the driving voltage Vdr according to the temperature through the voltage dividing unit 130, and adjusts the driving voltage Vdr to an adjusted driving voltage Vdr according to the temperature through the adjusting unit 140. Therefore, the driving voltage adjusting circuit 100 of the present disclosure dynamically adjusts the driving voltage Vdr according to the temperature of the switching elements Ta and Tb in the voltage converter 10, which can prevent the power loss of the voltage converter 10 from increasing with temperature.

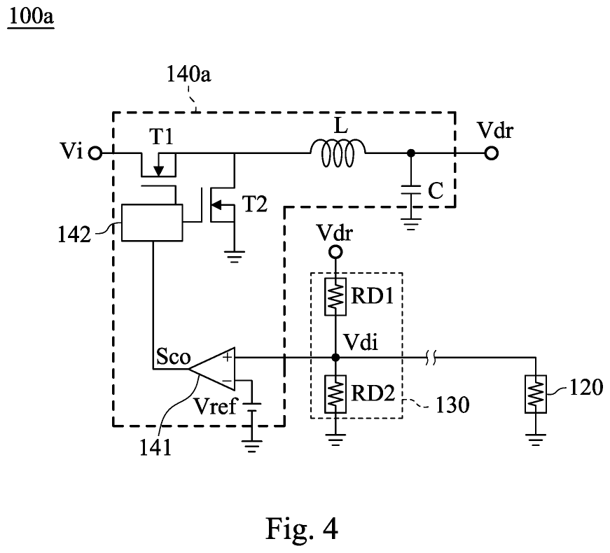

Reference is made to FIG. 1 and FIG. 4. FIG. 4 is a schematic diagram illustrating a driving voltage adjusting circuit 100a according to a second embodiment of the present disclosure. The driving voltage adjusting circuit 100a includes a detecting unit 120, a voltage dividing unit 130, and an adjusting unit 140a. In the second embodiment, the detecting unit 120 and the voltage dividing unit 130 operate in the same way as the detecting unit 120 and the voltage dividing unit 130 of the driving voltage adjusting circuit 100 in the first embodiment, and will not be described again. In particular, the adjusting unit 140a is a DC-DC converter, which may include a power amplifier 141, a pulse width modulation controller 142 and a switching element set. The power amplifier 141 is electrically connected to the voltage dividing unit 130, and generates a comparison signal Sco according to a dividing voltage Vdi. The pulse width modulation controller 142 is electrically connected to the power amplifier 141, and generates a pulse signal according to the comparison signal Sco. The switching element set is electrically connected to the pulse width modulation controller 142, and adjusts an input voltage Vi according to the pulse signal to output a driving voltage Vdr. The switching element set may include switching elements T1 and T2. Furthermore, the adjusting unit 140a may further include a filter unit (not shown). The filter unit is electrically connected between the switching element set and a voltage converter (not shown) to reduce noise in the driving voltage Vdr. The voltage converter may have the same structure as the voltage converter 10 in FIG. 2, and the filter unit includes an inductor L and a capacitor C.

In detail, the detecting unit 120 is a thermistor, and the voltage dividing unit 130 may include two resistors RD1 and RD2, where the two resistors RD1 and RD2 are connected in series and are connected in parallel with the detecting unit 120. When the detecting unit 120 detects that the temperature of the switching elements Ta and Tb rises, a resistance value of the detecting unit 120 decreases, causing the dividing voltage Vdi to decrease accordingly. The power amplifier 141 compares the dividing voltage Vdi with a reference voltage Vref to generate the comparison signal Sco. The pulse width modulation controller 142 adjusts a switching frequency of a generated pulse according to the comparison signal Sco, thereby increasing the driving voltage Vdr, and inputs the adjusted driving voltage Vdr to the voltage converter.

For example, when the resistor RD1 is 12 KΩ (ohms) and the resistor RD2 is 1.8 KΩ, the required driving voltage Vdr for the voltage converter may be as shown in Table 1. As can be seen from Table 1, when the temperature around the detecting unit 120 rises, the resistance value of the detecting unit 120 decreases, and the driving voltage Vdr generated by the adjusting unit 140a rises accordingly. In this way, the driving voltage adjusting circuit 100a of the present disclosure detects the temperature of the switching elements Ta and Tb having the highest temperature in the voltage converter through the detecting unit 120, and provides feedback to the adjusting unit 140a according to the temperature through the voltage dividing unit 130, so as to increase the driving voltage Vdr through the adjusting unit 140a, thereby driving the voltage converter with a higher voltage, and improving the conversion efficiency of the voltage converter.

TABLE 1

| | | | Equivalent resistance | |
|---|---|---|---|---|
| | Resistance value | | value of the resistor | Driving |
| | of the detecting | | RD2 and the detecting | voltage |
| Temperature | unit 120 | | unit 120 | Vdr |
| 0° C. | 357 | KΩ | 1.771 KΩ | 6.220 V |
| 5° C. | 273 | KΩ | 1.768 KΩ | 6.228 V |
| 10° C. | 210 | KΩ | 1.765 KΩ | 6.239 V |
| 15° C. | 163 | KΩ | 1.761 KΩ | 6.252 V |
| 20° C. | 127 | KΩ | 1.755 KΩ | 6.269 V |
| 25° C. | 100 | KΩ | 1.749 KΩ | 6.289 V |
| 30° C. | 79.22 | KΩ | 1.741 KΩ | 6.314 V |
| 35° C. | 63.17 | KΩ | 1.731 KΩ | 6.345 V |
| 40° C. | 50.68 | KΩ | 1.720 KΩ | 6.383 V |
| 45° C. | 40.90 | KΩ | 1.706 KΩ | 6.428 V |
| 50° C. | 33.20 | KΩ | 1.689 KΩ | 6.482 V |
| 55° C. | 27.09 | KΩ | 1.670 KΩ | 6.548 V |
| 60° C. | 22.22 | KΩ | 1.648 KΩ | 6.625 V |
| 65° C. | 18.32 | KΩ | 1.622 KΩ | 6.717 V |

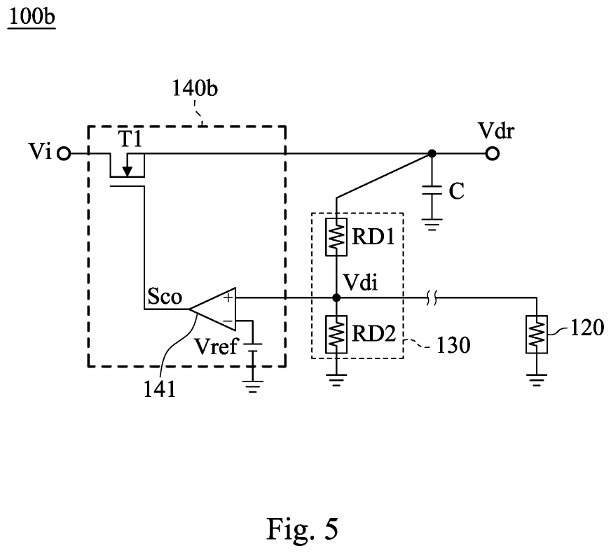

Reference is made to FIG. 1 and FIG. 5. FIG. 5 is a schematic diagram illustrating a driving voltage adjusting circuit 100b according to a third embodiment of the present disclosure. The driving voltage adjusting circuit 100b includes a detecting unit 120, a voltage dividing unit 130, and an adjusting unit 140b. In the third embodiment, the detecting unit 120 and the voltage dividing unit 130 operate in the same way as the detecting unit 120 and the voltage dividing unit 130 of the driving voltage adjusting circuit 100 in the first embodiment, and will not be described again. In particular, the adjusting unit 140b may be an LDO, which may include a power amplifier 141 and a switching element T1. The power amplifier 141 is electrically connected to the voltage dividing unit 130, and generates a comparison signal Sco according to a dividing voltage Vdi. The switching element T1 is electrically connected to the power amplifier 141 and adjusts an input voltage Vi according to the comparison signal Sco to output a driving voltage Vdr.

Furthermore, the power amplifier 141 compares the dividing voltage Vdi with a reference voltage Vref to generate the comparison signal Sco, and adjusts the input voltage Vi to the driving voltage Vdr according to the comparison signal Sco. Thus, the driving voltage adjusting circuit 100b of the present disclosure dynamically adjusts the driving voltage Vdr according to a temperature of a voltage converter (not shown), thereby reducing the cost of heat dissipation components in the voltage converter.

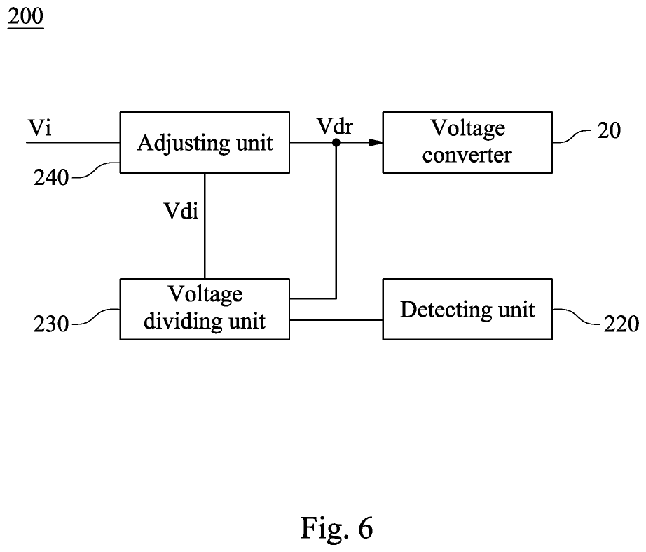

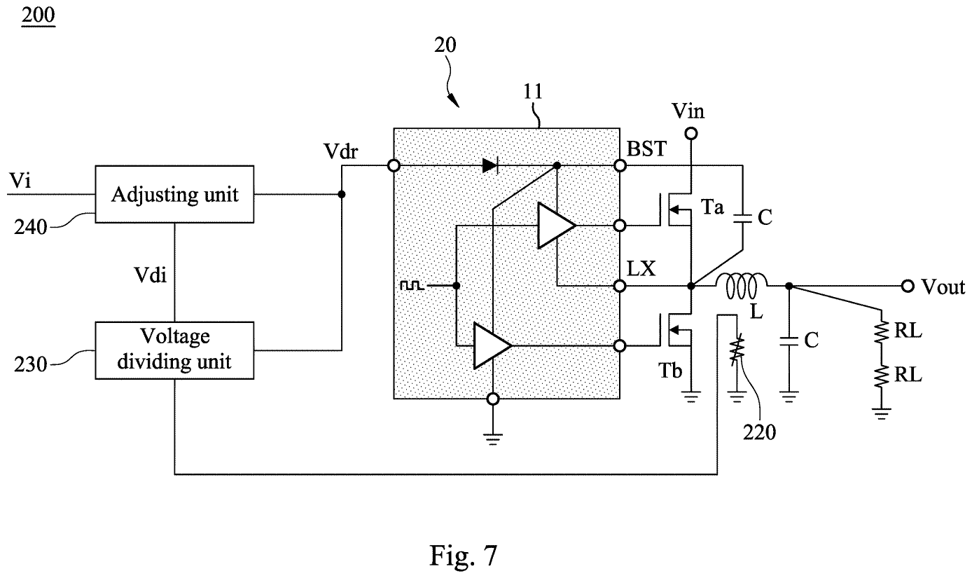

Reference is made to FIG. 6 and FIG. 7. FIG. 6 is a schematic diagram illustrating a power supplying system 200 according to a fourth embodiment of the present disclosure. FIG. 7 is a circuit schematic diagram of the power supplying system 200 according to FIG. 6. The power supplying system 200 includes a voltage converter 20 and a driving voltage adjusting circuit (not labeled). The voltage converter 20 is driven by a driving voltage Vdr and includes a switching element set. The switching element set includes two switching elements Ta and Tb. The driving voltage adjusting circuit includes a detecting unit 220, a voltage dividing unit 230 and an adjusting unit 240. The detecting unit 220 is disposed adjacent to one of the two switching elements Ta and Tb, and is configured to detect a temperature of the one of the two switching elements. In FIG. 7, as an example, the detecting unit 220 is disposed adjacent to the switching element Tb, and is configured to detect a temperature of the switching element Tb. In the fourth embodiment, the voltage dividing unit 230 and the adjusting unit 240 may operate in the same way as the voltage dividing unit 130 and the adjusting unit 140 in the first embodiment, and the voltage converter 20 can have the same structure as the voltage converter 10 in FIG. 2, which will not be described again. Therefore, the power supplying system 200 of the present disclosure can dynamically adjust the driving voltage Vdr according to a temperature of the voltage converter 20 to reduce the power loss generated when the switching elements Ta and Tb are switched and improve the overall efficiency of the power supplying system 200.

Although the present disclosure has been disclosed as above in embodiments, the embodiments are not intended to limit the present disclosure, and those of ordinary skill in the art may make some changes and embellishments within the spirit and scope of the present disclosure, therefore, the scope of protection of the present disclosure shall be defined in the attached claims.

What is claimed is:

1. A driving voltage adjusting circuit, comprising:
a detecting unit, disposed adjacent to a switching element of a voltage converter, and configured to detect a temperature of the switching element of the voltage converter;
a voltage dividing unit, electrically connected to the detecting unit and the voltage converter, and receiving a driving voltage, the voltage dividing unit dividing the driving voltage according to the temperature of the switching element to generate a dividing voltage; and
an adjusting unit, electrically connected to the voltage dividing unit, and receiving an input voltage and the dividing voltage, the adjusting unit adjusting the input voltage according to the dividing voltage to output the driving voltage, and the driving voltage being transmitted to the voltage converter;
wherein the temperature is positively correlated with the driving voltage.

2. The driving voltage adjusting circuit according to claim 1, wherein the adjusting unit is a DC-DC converter or a low dropout regulator.

3. The driving voltage adjusting circuit according to claim 1, wherein the adjusting unit comprises:
a power amplifier, electrically connected to the voltage dividing unit, and generating a comparison signal according to the dividing voltage;
a pulse width modulation controller, electrically connected to the power amplifier, and generating a pulse signal according to the comparison signal; and
a switching element set, electrically connected to the pulse width modulation controller, and adjusting the input voltage according to the pulse signal to output the driving voltage.

4. The driving voltage adjusting circuit according to claim 3, wherein the adjusting unit further comprises:
a filter unit, electrically connected between the switching element set and the voltage converter.

5. The driving voltage adjusting circuit according to claim 1, wherein the adjusting unit comprises:
a power amplifier, electrically connected to the voltage dividing unit, and generating a comparison signal according to the dividing voltage; and
another switching element, electrically connected to the power amplifier, and adjusting the input voltage according to the comparison signal to output the driving voltage.

6. A power supplying system, comprising:
a voltage converter, driven by a driving voltage, and comprising:
a switching element set, comprising two switching elements; and
a driving voltage adjusting circuit, comprising:
a detecting unit, disposed adjacent to one of the two switching elements, and configured to detect a temperature of the one of the two switching elements;
a voltage dividing unit, electrically connected to the detecting unit and the voltage converter, and receiving the driving voltage, the voltage dividing unit dividing the driving voltage according to the temperature of the one of the two switching elements to generate a dividing voltage; and
an adjusting unit, electrically connected to the voltage dividing unit, and receiving an input voltage and the dividing voltage, the adjusting unit adjusting the input voltage according to the dividing voltage to output the driving voltage, and the driving voltage being transmitted to the voltage converter;
wherein the temperature is positively correlated with the driving voltage.

7. The power supplying system according to claim 6, wherein the adjusting unit is a DC-DC converter or a low dropout regulator.

8. The power supplying system according to claim 6, wherein the adjusting unit comprises:
a power amplifier, electrically connected to the voltage dividing unit, and generating a comparison signal according to the dividing voltage;
a pulse width modulation controller, electrically connected to the power amplifier, and generating a pulse signal according to the comparison signal; and
another switching element set, electrically connected to the pulse width modulation controller, and adjusting the input voltage according to the pulse signal to output the driving voltage.

9. The power supplying system according to claim 8, wherein the adjusting unit further comprises:
a filter unit, electrically connected between the another switching element set and the voltage converter.

10. The power supplying system according to claim 6, wherein the adjusting unit comprises:
a power amplifier, electrically connected to the voltage dividing unit, and generating a comparison signal according to the dividing voltage; and
another switching element, electrically connected to the power amplifier, and adjusting the input voltage according to the comparison signal to output the driving voltage.
